(19) United States
(12) Patent Application Publication
(10) Pub. No.: US 2006/0286718 A1
(43) Pub. Date: Dec. 21, 2006

(54) Manufacturing method capable of simultaneously sealing a plurality of electronic parts

(75) Inventor: Kyosuke Ozaki, Fukushima-ken (JP)

Correspondence Address: BEYER WEAVER & THOMAS, LLP, P.O. BOX 70250, OAKLAND, CA, 94612-0250, US

(73) Assignee: ALPS ELECTRIC CO., LTD.

(21) Appl. No.: 11/415,580

(22) Filed: May 1, 2006

(30) Foreign Application Priority Data
Jun. 17, 2005 (JP) 2005-177490

(51) Int. Cl. H01L 21/00

(52) U.S. Cl. 438/113

(57) ABSTRACT

In order to increase production efficiency of an electronic part, the electronic parts in a wafer state are simultaneously sealed.

A method of manufacturing an electronic part includes a first step of forming a predetermined circuit pattern on a base substrate body 11 having a wafer shape in each device forming region 11a; a second step of disposing a mounting substrate body 12 having a wafer shape to face the base substrate body 11 and bonding the substrate bodies to each other; a third step of cutting only the base substrate body 11 in each device forming region 11a to be divided into individual base substrates 11A; a fourth step of integrally forming a sealing member 19A for sealing the divided individual base substrates 11A; and a fifth step of cutting the mounting substrate body 12 and the sealing member 19A to be divided into individual electronic parts 10.

### BACKGROUND OF THE INVENTION

1. Field of the Invention

The present invention relates to a method of manufacturing an electronic part such as a surface acoustic wave (SAW) device, and more particularly, to a method of manufacturing an electronic part capable of improving production efficiency.

2. Description of the Related Art

In a first method of manufacturing a surface acoustic wave device which was conventionally known, first, a metal pattern such as a comb-like electrode and a plurality of terminal electrodes is formed on one surface of a piezoelectric wafer in a block unit and a metal bump is formed on the terminal electrodes by bonding. The piezoelectric wafer is cut using a dicing method in each block unit to be divided into individual surface acoustic wave devices.

Next, a base substrate, in which a device connection terminal formed on one surface thereof and an external terminal electrode formed on the other surface thereof are connected to each other through a via, is prepared, and one surface of the surface acoustic wave device, on which the comb-like electrode is formed, is disposed to face the surface of the base substrate, on which the device connection terminal is formed, and the metal bump is attached to the device connection terminal on the base substrate, such that the surface acoustic wave device (terminal electrode) and the base substrate (device connection terminal) are mechanically and electrically connected to each other through the metal bump.

Next, a sealing resin having a sheet shape is pressed and heated on one surface of the plurality of surface acoustic wave devices such that the plurality of surface acoustic wave devices are simultaneously sealed. Finally, the base substrate and the sealing resin having the sheet shape are cut using the dicing method such that the sealed individual surface acoustic wave devices are obtained.

In addition, in a second method which was conventionally known, a resin sheet is laminated on a plurality of individual surface acoustic wave devices formed on a base substrate and the plurality of the individual surface acoustic wave devices are cut, thereby obtaining sealed individual surface acoustic wave devices.

However, in the first manufacturing method, the surface acoustic wave devices, which are in a wafer state just after completion, are cut to be divided into the individual surface acoustic wave devices and the divided surface acoustic wave devices are positioned and sealed at predetermined positions on a mounting substrate.

In addition, in the second manufacturing method, the divided SAW chips (surface acoustic wave device) are loaded on the mounting substrate at the plurality of positions and the wiring pattern on the mounting substrate and the connection pad on the SAW chip are connected to each other using the conductive bump, thereby performing flip-chip mounting.

To this end, in the first manufacturing method or the second manufacturing method, the directions or the orientations of the individual surface acoustic wave devices need be arranged in order and the individual surface acoustic wave devices need be positioned one by one. Accordingly, it takes much effort or time to seal the surface acoustic wave devices and thus productivity is reduced.

### SUMMARY OF THE INVENTION

The present invention is to solve the conventional problem, and it is an object of the present invention to provide a method of manufacturing an electronic part capable of improving production efficiency by simultaneously sealing electronic parts which are in a wafer state.

According to a first aspect of the present invention, there is provided a method of manufacturing an electronic part including: a first step of forming a predetermined circuit pattern on a base substrate body having a wafer shape in each device forming region; a second step of disposing a mounting substrate body having a wafer shape to face the base substrate body and bonding the substrate bodies to each other; a third step of cutting only the base substrate body in each device forming region to be divided into individual base substrates;

a fourth step of integrally forming a sealing member for sealing the divided individual base substrates; and a fifth step of cutting the mounting substrate body and the sealing member to be divided into individual electronic parts.

According to a second aspect of the present invention, there is a method of manufacturing an electronic part including: a first step of forming a predetermined circuit pattern on a base substrate body having a wafer shape in each device forming region and forming a plurality of grooves for defining the device forming regions; a second step of disposing a mounting substrate body having a wafer shape to face the base substrate body and bonding the substrate bodies to each other; a third step of polishing the base substrate body to be divided into individual base substrates; a fourth step of integrally forming a sealing member for sealing the divided individual base substrates; and a fifth step of cutting the mounting substrate body and the sealing member to be divided into individual electronic parts.

In the first and second aspects, it is possible to collectively seal the electronic parts which are in the wafer state. To this end, when dividing, the sealed electronic parts can be obtained and production efficiency of the electronic parts can be improved.

The sealing member may be a metal layer formed by any one of a sputtering method, an electric plating method, a nonelectrolytic plating, or a deposition method.

By this configuration, since the individual electronic parts are covered with the metal layer, it is possible to improve sealing performance.

In addition, the sealing member may be a resin material formed by a transfer molding method or an insert molding method.

By this configuration, since the individual electronic parts are covered with the sealing member made of resin, it is possible to improve sealing performance.

In addition, the sealing member closely may adhere a heated thermosetting resin sheet to the base substrates.

By this configuration, it is possible to easily or simply seal the plurality of electronic parts which are in the wafer state. To this end, it is possible to improve the production efficiency.

For example, a piezoelectric substrate may be used as the base substrate and a comb-like electrode may be formed as the circuit pattern. In other words, it is possible to obtain a surface acoustic wave device.

In the method of manufacturing the electronic part according to the present invention, since the electronic parts are sealed in the wafer state before dividing, it is possible to improve the production efficiency of the electronic part and to provide an electronic part having higher sealing performance.

### BRIEF DESCRIPTION OF THE DRAWINGS

FIG. 1 is a cross-sectional view showing a structure of an electronic part manufactured by a manufacturing method according to the present invention;

FIG. 2 is a process view showing a method of manufacturing an electronic part according to a first embodiment of the present invention;

FIG. 3 is a process view showing main steps in a method of manufacturing an electronic part according to a second embodiment of the present invention;

FIG. 4 is a process view showing main steps in a method of manufacturing an electronic part according to a third embodiment of the present invention; and

FIG. 5 is a process view showing main steps in a method of a fifth embodiment of the present invention.

### DESCRIPTION OF THE PREFERRED EMBODIMENTS

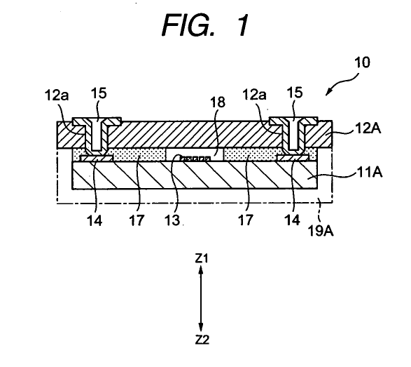

FIG. 1 is a cross-sectional view showing a structure of an electronic part manufactured by a manufacturing method according to the present invention. An electronic part 10 shown in FIG. 1 is, for example, a band pass filter formed using a surface acoustic wave device. Meanwhile, the surface acoustic wave device having a simple structure is, for example, used as a device suitable for miniaturizing a filter, a resonator, or a duplexer mounted in a mobile communication terminal.

As shown in FIG. 1, the electronic part 10 includes a base substrate 11A and a mounting substrate 12A, which face each other at a predetermined distance. The base substrate 11A of the present embodiment is made of a piezoelectric material, and a pair of comb-like electrodes (inter-digital transducer (IDT) electrode) made of a conductive material and terminal electrodes 14 and 14 continuously connected to ends of the comb-like electrodes 13 are formed on a surface (surface of a Z1 side) of the base substrate 11A.

Meanwhile, when the electronic part 10 is not a surface acoustic wave device, a circuit pattern made of a different conductive material or a circuit pattern made of a resistor film or a dielectric film for a capacitor is formed.

Through-holes 12a and 12a are formed in a mounting substrate body 12 in a plate thickness direction (Z direction) and through-electrodes 15 and 15 formed using a method such as a sputtering method or a plating method is formed in the through-holes 12a and 12a. One ends (ends of the Z1 side) of the through-electrodes 15 and 15 are exposed to the surface of the mounting substrate 12A and the other ends (ends of a Z2 side) thereof are connected to the surfaces of the terminal electrodes 14 and 14 which are the ends of the comb-like electrodes 13 formed on the base substrate 11A.

In a region in which the base substrate 11A and the mounting substrate 12A face each other, an adhesive layer 17 is disposed on a portion except a center portion in which the comb-like electrodes 13 is provided, and the base substrate 11A and the mounting substrate 12A are fixed to each other through the adhesive layer 17. Meanwhile, the center portion without the adhesive layer is a hollow region 18 for propagating a surface acoustic wave to the comb-like electrode 13s.

In addition, a sealing member 19A is sealed on the periphery of the base substrate 11A and the lower surface of the mounting substrate 12A.

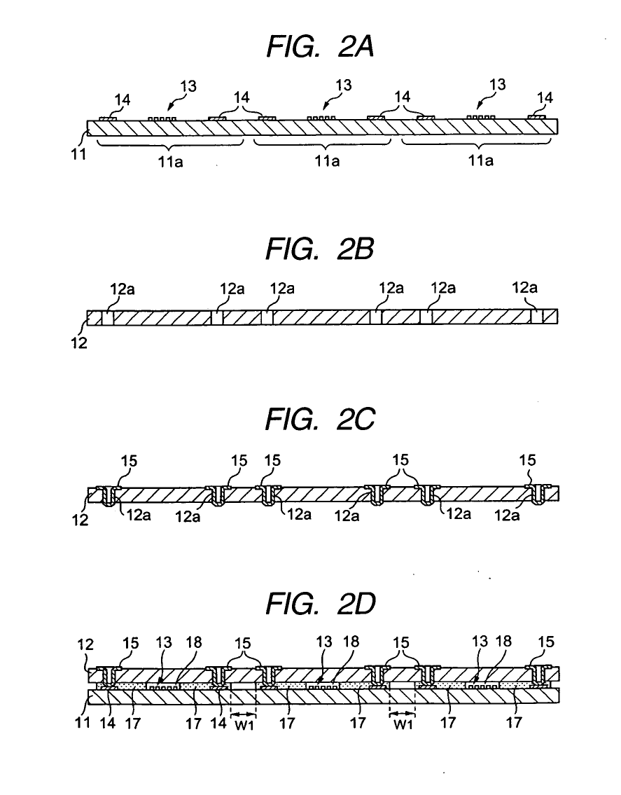

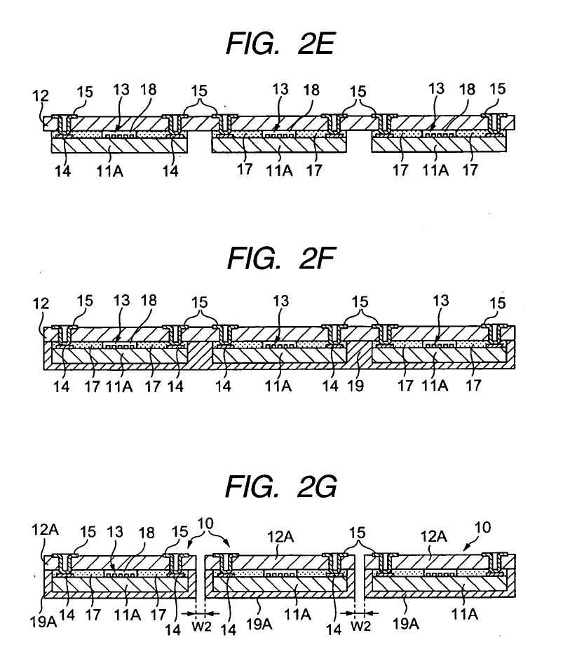

Next, a method of manufacturing the electronic part will be described. FIG. 2 is a process view showing a method of manufacturing an electronic part according to a first embodiment of the present invention.

In a step shown in FIG. 2A, a base substrate body 11 having a wafer shape is prepared, in which a plurality of flat device forming regions 11a, 11a, . . . is formed on a surface (surface of a Z1 side) thereof. In addition, the comb-like electrode 13 (inter-digital transducer (IDT) electrode) is formed on each of the device forming regions 11a (first step) as a predetermined circuit pattern. In other words, the surface acoustic wave substrate having the wafer shape is formed.

Meanwhile, when the electronic part 10 formed by this manufacturing method is not the surface acoustic wave device, for example, the other circuit pattern such as a resistor film, a dielectric film for a capacitor, or an eddy pattern for a coil may be formed, instead of the comb-like electrode 13.

In a step shown in FIG. 2B, a mounting substrate body 12 having a wafer shape is prepared and the through-holes 12a and 12a are formed in the mounting substrate body 12 at positions corresponding to the device forming regions 11a, 11a, . . . . Meanwhile, the mounting substrate body 12 having a wafer shape, in which through-holes 12a and 12a are previously formed, may be purchased or through-holes 12a and 12a may be formed in a mounting substrate body 12 after the mounting substrate body 12 having a wafer shape is purchased.

In a step shown in FIG. 2C, the through-electrodes 15 and 15 made of a conductive material, such as copper, silver, or gold, are formed in the through-holes 12a and 12a to face the terminal electrodes 14 and 14 on the base substrate body 11. The through-electrodes 15 and 15 may be formed by any one of a sputtering method, an electric plating method, or a nonelectrolytic plating method.

In a step shown in FIG. 2D, an adhesive layer 17 is provided on the base substrate body 11 having the wafer shape, which is formed in FIG. 2A, and the mounting substrate body 12 having the wafer shape, which is formed in FIG. 2B, is loaded thereon, thereby bonding the base substrate body 11 and the mounting substrate body 12 to each other (second step).

The adhesive layer 17 is provided on a region except a center portion in each device forming region 11a, on which the comb-like electrode 13 is formed. Accordingly, when the base substrate body 11 and the mounting substrate body 12 are bonded to each other through the adhesive layer 17, the hollow region 18 by which the comb-like electrode 13 is exposed is formed in the center portion of the device forming region 11a. By the hollow region 18, it is possible to propagate a surface acoustic wave-to the comb-like electrode 13.

In a step shown in FIG. 2E, only the base substrate body 11 is cut between the device forming region 11a and the device forming region 11a, which are adjacent to each other, with a predetermined cut width W1 (third step). Meanwhile, even after only the base substrate body 11 is cut, the electronic parts 10 are connected to one another through the mounting substrate body 12. To this end, the electronic parts 10 are not divided.

As a cutting method, various methods such as a dicing process, a laser process, a milling process using an end mill, a dry etching method, or a wet etching method may be used.

In a step shown in FIG. 2F, a liquid resin material 19 such as epoxy or polyimide is filled on the periphery of the individually cut base substrate 11A and on a lower surface of the mounting substrate body 12 such that the periphery of the base substrate 11A is integrally closed and sealed by a sealing member 19 made of the resin material 19A (fifth step).

As a method of filling the resin material 19, for example, various methods such as a transfer molding method or an insert molding method of mounting the lower side (base substrate 11A) of the mounting substrate body 12 in a mold cavity and inserting the molten resin material 19 into the heated mold cavity may be used.

In a step shown in FIG. 2G, the mounting substrate body 12 and the resin material 19 after curing are divided by the above-described dicing process in a unit of the device forming region 11a (sixth step). At this time, when the cut width W2 of the step shown in FIG. 2G is narrower than the cut width W1 of the step shown in FIG. 2E (W1>W2), it is possible to prevent a failure such as a sealing failure due to the exposure of a portion of the base substrate 11A from the sealing member 19A. In other words, it is possible to completely seal the electronic part 10A by the sealing member 19A and the mounting substrate 12A mounted thereon. Accordingly, since the circuit pattern (comb-like electrode 13 and the terminal electrodes 14) provided in the hollow region 18 can be blocked from the outside (external air), it is possible to provide the electronic part 10A having excellent sealing performance.

As described above, in the manufacturing method according to the first embodiment, the circuit patterns or the electrodes of the electronic parts 10 can be integrally formed in the wafer state. In addition, the sealing member 19A for sealing the individual electronic parts 10 can be integrally and simultaneously in the wafer state. Accordingly, it is possible to significantly. improve production efficiency, compared with the conventional method.

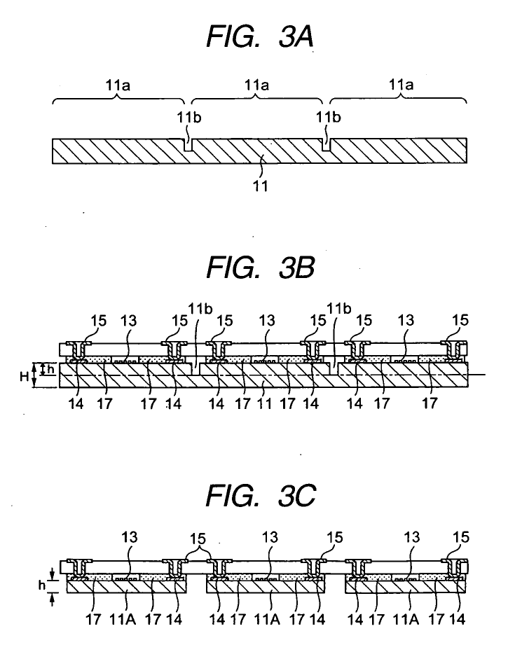

FIG. 3 is a process view showing main steps in a method of manufacturing an electronic part according to a second embodiment of the present invention. Meanwhile, the second embodiment is similar to the first embodiment and thus different steps will be mainly described.

First, in the second embodiment, a step shown in FIG. 3A is different from the step shown in FIG. 2A (first step) in that a plurality of grooves 11b for defining the device forming regions 11a is formed on the base substrate body 11 (first step). The step of forming the grooves 11b may be performed before or after the step of forming the circuit pattern such as the comb-like electrode 13 or the terminal electrode 14. Meanwhile, the grooves 11b are formed on the base substrate body 11 in a flat matrix shape.

Next, the same steps as that shown in FIGS. 2B to 2D are performed. In other words, as shown in FIG. 3B, a plurality of through-electrodes 15 is formed at positions facing the device forming regions 11a, 11a, . . . on the mounting substrate body 12 and the base substrate body 11 having the wafer shape and the mounting substrate body 12 having the wafer shape are bonded to each other using an adhesive 17 (second step).

In a next step, the bottom of the base substrate body 11 is polished (see FIG. 3C). In this step, when the base substrate body 11 having the wafer shape is polished and a plate thickness H of the base substrate body 11 is equal to a depth h of the groove 11b, the individual base substrate 11A can be divided from the base substrate body 11 having the wafer shape (third step).

In addition, by performing the same steps as those shown in FIGS. 2F and 2G, the individual electronic part 10 is formed. In other words, the sealing member 19A made of the resin material 19 is formed on the periphery of the divided individual base substrate 11A (fourth step) and the adjacent device forming regions 11a are cut, thereby completing the individual electronic parts 10 (fifth step).

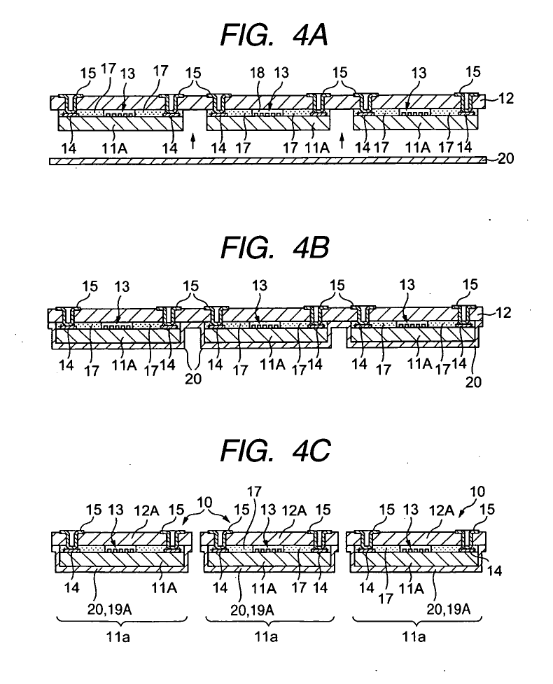

FIG. 4 is a process view showing main steps in a method of manufacturing an electronic part according to a third embodiment of the present invention. Meanwhile, the second embodiment is similar to the first and second embodiments and thus different steps will be mainly described.

The steps of the third embodiment follow the step of FIG. 2E of the first embodiment. In other words, the first to third steps are similar to those of the first embodiment. In addition, FIG. 4A shows the same step as those of FIGS. 2F and 3C.

As shown in FIG. 4A, in the steps of the third embodiment, a thermosetting resin sheet 20 is closely adhered to the lower side (base substrate 11A) of the individual electronic parts 10 connected to one another by the mounting substrate body 12 having the wafer shape using a compression pneumatic molding (also referred to as “pneumatic molding” or “pressure molding”).

As shown in FIG. 4B, by lengthening and deforming the heated and softened resin sheet 20 with compressed air to have the same shape as that of the base substrate 11A, the resin sheet 20 is integrally adhered to the respective base substrates 11A (fourth step).

In addition, as shown in FIG. 4C, after curing, the mounting substrate body 12 is cut between the device forming region 11a and the device forming region 11a, which are adjacent to each other, the respective electronic parts 10 are separated from the mounting substrate body 12 (fifth step). In the third embodiment, the sealing member 20 covering the base substrate 11A functions as the sealing member 19A of the first embodiment (or the second embodiment).

Even in the third embodiment, the plurality of electronic parts 10 can be integrally and simultaneously formed in the wafer state. In addition, the resin sheet 20 which functions as the sealing member 19A blocking the inside and the outside of the individual electronic parts 10 can be integrally and simultaneously formed. To this end, it is possible to significantly improve the production efficiency compared with the conventional method.

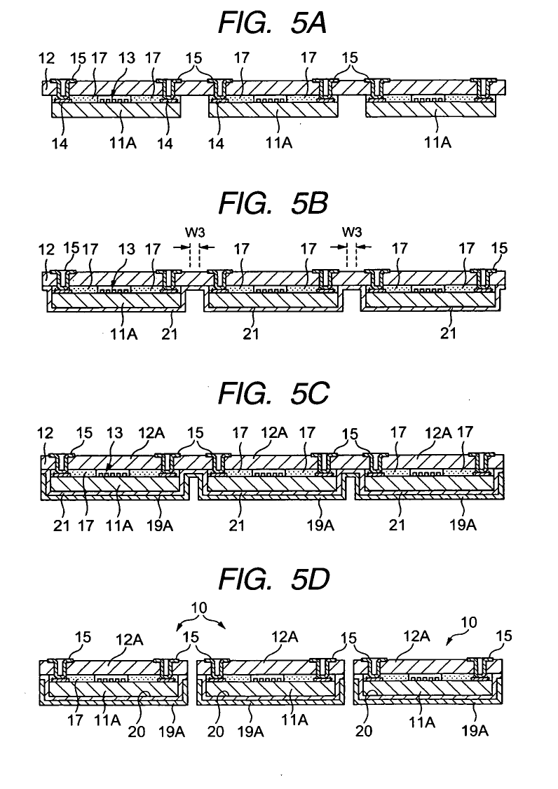

Next, a fourth embodiment of the present invention will be described. FIG. 5 is a process view showing main steps in a method of a fifth second embodiment of the present invention.

FIG. 5A is similar to the step shown in FIG. 2E or FIG. 3C and shows the divided individual base substrates 11A.

In a step shown in FIG. 5B, the base substrate 11A is covered with a metal layer 21 by performing a sputtering method, an electric plating method, or a deposition method on the base substrate 11A.

In this state, when the cut step is performed with the cut width W3 as described above, it is possible to form the individual electronic parts 10 in which the base substrate 11A is sealed by the sealing member including the metal layer 21.

In the fourth embodiment, since the base substrate 11A is covered with the metal layer 21, it is possible to provide an electronic part having high sealing performance.

In addition, in the electronic part 10 having the high sealing performance, as shown in FIG. 5C, the metal layer 21 may be covered with the above-described sealing member (resin material or resin sheet) 19A before the cut step and the substrate may be divided into the individual electronic parts 10 (see FIG. 5D). In this case, since the base substrate 11A is doubly sealed by the metal layer 21 and the resin sealing member 19A, it is possible to provide the electronic part 10 having higher sealing performance.

Meanwhile, by alternately forming a resin material and a metal material, or laminating a resin material or a metal material on a resin material, that is, doubly or trebly laminating various materials, it is possible to more improve the sealing performance.

Although, in the embodiments, a surface acoustic device is described as an example of an electronic part 10, the present invention is not limited to the embodiments. The present invention is applicable to any electronic part which requires sealing.

What is claimed is:

1. A method of manufacturing an electronic part comprising:
a first step of forming a predetermined circuit pattern on a base substrate body having a wafer shape in each device forming region;
a second step of disposing a mounting substrate body having a wafer shape to face the base substrate body and bonding the substrate bodies to each other;
a third step of cutting only the base substrate body in each device forming region to be divided into individual base substrates;
a fourth step of integrally forming a sealing member for sealing the divided individual base substrates; and
a fifth step of cutting the mounting substrate body and the sealing member to be divided into individual electronic parts.

2. A method of manufacturing an electronic part comprising:
a first step of forming a predetermined circuit pattern on a base substrate body having a wafer shape in each device forming region and forming a plurality of grooves for defining the device forming regions;
a second step of disposing a mounting substrate body having a wafer shape to face the base substrate body and bonding the substrate bodies to each other;
a third step of polishing the base substrate body to be divided into individual base substrates;
a fourth step of integrally forming a sealing member for sealing the divided individual base substrates; and
a fifth step of cutting the mounting substrate body and the sealing member to be divided into individual electronic parts.

3. The method of manufacturing the electronic part according to claim 1, wherein the sealing member is a metal layer formed by any one of a sputtering method, an electric plating method, a nonelectrolytic plating, or a deposition method.

4. The method of manufacturing the electronic part according to claim 1, wherein the sealing member is a resin material formed by a transfer molding method or an insert molding method.

5. The method of manufacturing the electronic part according to claim 1, wherein the sealing member closely adheres a heated thermosetting resin sheet to the base substrates.

6. The method of manufacturing the electronic part according to claim 1, wherein a piezoelectric substrate is used as the base substrate and a comb-like electrode is formed as the circuit pattern.
